(19) United States
(12) Patent Application Publication
(10) Pub. No.: US 2010/0084007 A1
(43) Pub. Date: Apr. 8, 2010

(54) MODIFIED CARBON NANOTUBE GRAFTED BY LIVING POLYMER, CARBON NANOTUBE ELECTRODE AND DYE-SENSITIZED SOLAR CELL USING THE SAME, AND EACH PREPARATION METHOD THEREOF

(76) Inventors: Seong-Mu JO, Seoul (KR); Dong-Young KIM, Seoul (KR); Sung-Yeon JANG, Daegu (KR); Soon-Jong KWAK, Seoul (KR); Jin-Kyu HAN, Gyeonggi-Do (KR)

Correspondence Address: OSTROLENK FABER GERB & SOFFEN, 1180 AVENUE OF THE AMERICAS, NEW YORK, NY, 100368403, US

(21) Appl. No.: 12/559,584

(22) Filed: Sep. 15, 2009

(30) Foreign Application Priority Data
Oct. 7, 2008 (KR) 10-2008-0098371

(51) Int. Cl. H01L 31/04; H01J 1/00; B05D 5/12; B05D 1/04; C08F 8/00

(52) U.S. Cl. 136/252; 313/311; 427/77; 427/458; 525/55; 977/939; 977/750; 977/752

(57) ABSTRACT

Disclosed are to provide a modified carbon nanotube obtained by reacting a polymer to a carbon nanotube by a radical graft method, capable of minimizing lowering of a physical property of a carbon nanotube caused when being modified, and capable of enhancing dispersibility of the carbon nanotube and an adhesion strength between carbon nanotubes, the polymer having a molecular weight controlled by a living radical polymerization and still having a living radical end group.

Also disclosed are to provide a carbon nanotube electrode and a dye-sensitized solar cell using the same, capable of forming a carbon nanotube film having a thickness thinner than that of the conventional electrode by directly spraying, on a substrate, by an electro-spray process, a uniform dispersion solution that the modified carbon nanotube is dispersed in a proper solvent without requiring an additional organic binder, capable of exhibiting an excellent catalytic characteristic owing to a close adhesion strength between carbon nanotubes and an increased relative density of the carbon nanotube film, and capable of implementing an excellent long-term stability owing to a strong bonding force between a carbon nanotube and a substrate.

### RELATED APPLICATION

The present disclosure relates to subject matter contained in priority Korean Application No. 10-2008-0098371, filed on Oct. 7, 2008, which is herein expressly incorporated by reference in its entirety.

### BACKGROUND OF THE INVENTION

1. Field of the Invention

The present invention relates to a modified carbon nanotube grafted by a living polymer capable of enhancing dispersibility of a carbon nanotube, an adhesion strength between a substrate and a carbon nanotube and a close adhesion strength between carbon nanotube particles, a carbon nanotube electrode and a dye-sensitized solar cell using the same, and each preparation method thereof.

2. Background of the Invention

Dye-sensitized solar cells were firstly introduced to the public by the Swiss Gratzel research team (B. O'Regan, M. Gratzel, Nature 353, 737 (1991)), and are being highly researched.

The dye-sensitized solar cell by Gratzel et al. utilizes an oxide semiconductor electrode comprising a photosensitized dye for generating an electron-hole pair by absorbing visible light, and nanocrystalline titanium oxide particles for delivering the generated electrons. More concretely, electrons excited in a dye by visible light are transferred to titanium oxide particles, an n-type semiconductor. Here, an empty space of a lower level of the dye, formed as the electrons are transferred, is filled again with electrons provided by ions inside an electrolyte according to the following formula (1) by means of an electrochemical redox (oxidation-reduction) reaction of “I⁻/I₃⁻”. The I₃⁻ ions generated by providing the electrons to the dye move to a counter electrode, a cathode, and then are reduced by receiving the electrons by a platinum catalyst of the counter electrode as shown in the following formula (2). The I₃⁻ ions repeat an electrochemical reaction.

3I⁻→I₃⁻+2e⁻(transfer to dye) (1)

I₃⁻+2e⁻(Pt catalyst-counter electrode)→3I⁻ (2)

That is, the counter electrode of the dye-sensitized solar cell serves, on its surface, as a catalyst for a redox reaction of ions that are inside an electrolyte, thereby providing electrons to the ions that are inside the electrolyte. For this, the conventional dye-sensitized solar cell uses a platinum thin film having an excellent catalytic activity. In some cases, the dye-sensitized solar cell may use palladium having a similar characteristic to platinum, precious metals such as gold and silver, and carbon-based electrodes such as carbon black and graphite.

Especially, a platinum electrode is being commonly used due to its high electric conductivity and excellent catalytic characteristic. However, the platinum electrode is expensive, and has a limitation in increasing a catalytic reaction speed of the entire dye-sensitized solar cell due to a limitation in increasing a surface area where a catalytic reaction occurs. Also, the platinum electrode has a degraded long-term stability. That is, as a catalytic reaction is repeated, the platinum catalyst is detached from a conductive substrate and is dissolved in an electrolyte, thereby lowering a photoelectric conversion efficiency.

Furthermore, in the conventional method, the platinum counter electrode is prepared by using expensive equipment using a vacuum process such as a sputtering method, or by using a screen printing method using expensive platinum compounds. Accordingly, in the case that a module of the solar cell is fabricated in a large area, the productivity is lowered in the economic aspects.

The carbon-based electrode is cheap, and can have a surface area larger than that of the platinum electrode. However, the carbon-based electrode may degrade the efficiency of the solar cell due to its inferior reaction speed to the platinum electrode.

Accordingly, in the conventional method, a very thick carbon film having a thickness of several tens of microns is applied to a counter electrode due to a slow reaction speed of carbon material. This may cause an internal resistance of an electrode film to be increased, thereby lowering a photoelectric conversion efficiency.

In the conventional method, a counter electrode is prepared by casting paste including carbon powder onto a substrate and then sintering the paste. When the paste is sintered at a high temperature, carbon is oxidized or the substrate is thermally degraded. Accordingly, the paste is sintered at a low temperature. This may degrade an adhesion strength between the substrate and the carbon nanotube, and a close adhesion strength between carbon particles. In order to solve this problem, paste including an organic binder may be used. However, since the organic binder remains in a porous carbon electrode, an area effective to an electrode reaction may be decreased.

Generally, a carbon nanotube (CNT) has an electric conductivity as same as that of metal, and has a specific surface area of several hundreds of m²/g which is much higher than that of bulk. Furthermore, the carbon nanotube has a very high tensile strength of 250˜300 GPa. The carbon nanotube has an excellent thermal conductivity of maximum 6000 W/mK at a room temperature, and a very excellent thermal stability of 750° in the air (Science American, December 2000, p 69). Accordingly, the carbon nanotube is being applied to various electronic devices, or is being utilized as a nanocomposites material and an energy storing material.

Research on a counter electrode using a carbon nanotube has been recently reported. The carbon nanotube exhibits an excellent catalytic activity against a redox reaction due to its wide specific surface area. And, the carbon nanotube has characteristics of increasing the electron transfer speed on the surface of the counter electrode due to its high electric conductivity.

Korean Patent Laid-Open Publication No. 2006-0033158 discloses a counter electrode prepared by using carbon nanotubes. Carbon nanotube powder, a dispersant, and an organic binder are mixed in a dispersion liquid, thereby preparing paste by selecting at least one of a ball milling method, a grinding method, a 3-roll milling method, and a high energy ball milling method according to a usage purpose. And, the carbon nanotube paste is coated on a substrate by one of a doctor blade method, a screen printing method, a spray method, a spin coating method, a painting method, and a dipping method. Then, the carbon nanotube paste is sintered at a temperature of 70˜350° C. to complete a carbon nanotube film, thereby preparing a carbon nanotube electrode. Since the carbon nanotube has a low catalytic reaction due to the presence of the organic binder, the counter electrode prepared according to these methods has to be provided with a thick carbon nanotube film having a thickness of several tens of microns. This may cause an internal resistance of the carbon nanotube film serving as a catalyst to be increased.

Japanese Patent Laid-Open Publication No. 2008-66018 discloses a method for preparing a carbon nanotube counter electrode having no organic binder by electro-depositing a carbon nanotube on a conductive substrate by immersing the conductive substrate into a solution obtained and thereby dispersing the carbon nanotube in an organic solvent having no organic binder. However, as a module of the carbon nanotube counter electrode has a larger area, required is a new catalyst counter electrode having a cheap price, a high surface area and a high electric conductivity.

In the case of fabricating counter electrodes and electronic devices using carbon nanotubes, dispersibility of the carbon nanotubes is very important. More concretely, in the case of using a solution having a low dispersibility of carbon nanotubes, the electronic devices have a low electric conductivity in spite of an excellent electric conductivity of the carbon nanotubes. Furthermore, since an adhesion strength between a transparent conductive substrate and a carbon nanotube film is not strong, the carbon nanotube film having been coated on the substrate may be detatched from the substrate or may flow. This may cause the counter electrode to have a shortened life span. And, a low close adhesion strength between carbon nanotubes causes an internal resistance of a carbon nanotube film to be increased, resulting in degrading the efficiency of the dye-sensitized solar cell.

Accordingly, in order to fabricate a counter electrode using a carbon nanotube, required is the carbon nanotube capable of having a stable carbon nanotube film by thereby more improving an electric conductivity characteristic and an adhesion of the carbon nanotube film like as enhancing an adhesion strength between the carbon nanotube film and a substrate, enhancing a close adhesion strength between carbon nanotubes and maintaining an excellent catalytic characteristic even on a thin carbon nanotube film, etc.

### SUMMARY OF THE INVENTION

Therefore, an object of the present invention is to provide a modified carbon nanotube grafted by a living polymer and a preparation method thereof capable of minimizing lowering of a physical property of a carbon nanotube caused when being modified, capable of enhancing dispersibility of a carbon nanotube, an adhesion strength between a substrate and a carbon nanotube, and a close adhesion strength between carbon nanotubes.

Another object of the present invention is to provide a carbon nanotube electrode and a preparation method thereof capable of forming a carbon nanotube film having a thickness thinner than that of the conventional carbon nanotube electrode by using a uniform dispersion solution that the modified carbon nanotube is dispersed in a proper solvent without requiring an additional organic binder, capable of exhibiting an excellent catalytic characteristic owing to a high close adhesion strength between carbon nanotubes and an increased relative density of the carbon nanotube film, and capable of implementing an excellent long-term stability owing to a strong adhesion strength between a carbon nanotube and a substrate.

Still another object of the present invention is to provide a dye-sensitized solar cell using the carbon nanotube electrode as a counter electrode.

Yet still another object of the present invention is to provide a transparent electrode based on a carbon nanotube instead of fluorine-doped tin oxide (FTO) or indium-doped tin oxide (ITO).

According to a first aspect, to achieve these and other advantages and in accordance with the purpose of the present invention, as embodied and broadly described herein, there is provided a modified carbon nanotube obtained by chemically bonding a polymer to a carbon nanotube by a radical graft reaction, the polymer synthesized by a living radical polymerization and having a living radical end group.

According to a second aspect, the present invention provides a method for preparing a modified carbon nanotube, comprising: preparing a polymer or oligomer synthesized by a living radical polymerization of an unsaturated monomer, and having a living radical end group; and reacting the polymer or oligomer with a carbon nanotube by a radical graft reaction, thereby chemically bonding the polymer or oligomer to the carbon nanotube.

According to a third aspect, the present invention provides a carbon nanotube electrode, comprising: a substrate; and a carbon nanotube film formed on the substrate, and including the modified carbon nanotube according to the first aspect.

According to a fourth aspect, the present invention provides a method for preparing a carbon nanotube electrode, comprising: preparing a dispersion solution that the modified carbon nanotube prepared by the method according to the second aspect is dispersed in a solvent; and forming a carbon nanotube film by depositing the dispersion liquid on a substrate.

According to a fifth aspect, the present invention provides a dye-sensitized solar cell, comprising: a semiconductor electrode; the carbon nanotube electrode according to the third aspect; and an electrolyte filled between the two electrodes.

The present invention has the following effects.

Firstly, a dispersion solution of a modified carbon nanotube having excellent dispersibility is electro-sprayed on a substrate. Accordingly, can be formed a carbon nanotube film having a thickness thinner than that of the conventional carbon nanotube, and can be implemented an excellent catalytic characteristic owing to a high close adhesion strength between carbon nanotubes, and an increased relative density of the carbon nanotube film. Also, can be implemented a carbon nanotube electrode having an excellent long-term stability owing to a strong adhesion strength between the carbon nanotube film and the substrate.

Secondly, the modified carbon nanotube according to the present invention has an excellent dispersibility. Accordingly, once a dispersion solution having the modified carbon nanotube is electro-sprayed on a substrate, the dispersion solution is coated on the substrate with a higher uniformity than in the conventional art. This results in an enhanced smoothness of a carbon nanotube film, thereby enhancing an adhesion strength between the substrate and the carbon nanotube film, and enhancing the workability.

Thirdly, the carbon nanotube electrode according to the present invention has an excellent catalytic characteristic, thus to be applied to various electrochemical apparatuses. And, owing to an excellent chemical stability, the carbon nanotube electrode has a life-span longer than that of the conventional electrode.

Fourthly, the carbon nanotube electrode according to the present invention may be used as a transparent electrode or a counter electrode for a dye-sensitized solar cell, and may replace ITO or FTO substrate owing to its high electric conductivity and an excellent adhesion strength between a carbon nanotube film and a substrate. This enables an expensive substrate having a transparent conductive film not to be required, resulting in low production costs and commercialization of dye-sensitized solar cells.

Fifthly, the carbon nanotube electrode according to the present invention has a thinner film and a more excellent photoelectric conversion efficiency than the conventional carbon nanotube electrode. Accordingly, a small amount of carbon nanotube are used, resulting in improving an economic efficiency.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is a schematic diagram showing a method for preparing a carbon nanotube modified by a radical graft reaction of a polymer according to a first embodiment of the present invention;

FIG. 2 is a schematic view showing an electro-spray method according to the present invention;

FIG. 3 shows a TGA analysis result of an MWNT-g-PSSNa prepared by a living radical graft reaction according to a first embodiment of the present invention;

FIG. 4 shows photos of a carbon nanotube electrode prepared by electro-spraying a dispersion solution of the carbon nanotube modified by a graft reaction according to a first embodiment of the present invention;

FIG. 5A shows a photo of a carbon nanotube electrode prepared by using an MWNT-g-PSSNa according to Example 2-4 of the preset invention; and

FIG. 5B shows a photo of a carbon nanotube electrode prepared by using an MWNT-g-PSSNa according to Example 2-8 of the preset invention.

### DETAILED DESCRIPTION OF THE INVENTION

Description will now be given in detail of the present invention, with reference to the accompanying drawings.

Generally, it is difficult to obtain a dispersion solution having excellent dispersibility from a carbon nanotube by an ultrasonic grinding method or a mechanical milling method. Once the carbon nanotube undergoes an acid or alkali treatment process, a chemical functional group is introduced into the surface of the carbon nanotube. Accordingly, the carbon nanotube has enhanced dispersibility. However, the enhanced dispersibility is not satisfied, and the carbon nanotube has a worse physicochemical characteristic due to the introduced chemical functional group. That is, an electric conductivity and a surface activation of the carbon nanotube are lowered.

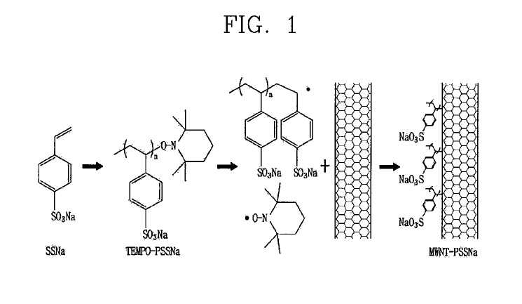

As shown in FIG. 1, the present invention provides a modified carbon grafted by reacting a living radical end group of a polymer to a carbon nanotube by a radical graft reaction, the polymer synthesized to have a well-controlled molecular weight and molecular weight distribution by a living radical polymerization, and still having the living radical end group (an end group that can generate free radicals at any time at a suitable reaction temperature).

Preferably, the polymer according to the present invention has a molecular weight of 10,000 or less. When the polymer has a molecular weight more than 10, 000, an electric conductivity of the carbon nanotube may be lowered since the amount of the polymer is greater than that of the carbon nanotube. In the present invention, the polymer includes oligomer.

In the present invention, a carbon nanotube having undergone no acid or alkali process is used in a graft reaction. Preferably, a modified carbon nanotube, a carbon nanotube electrode and a dye-sensitized solar cell using the same satisfy the following three conditions, so as to minimize lowering of an electric conductivity and a surface activation of a carbon nanotube caused when polymers are grafted to the carbon nanotube.

Firstly, in order to minimize lowering of an electric conductivity and a surface activation of a carbon nanotube and to maximize dispersibility in a solvent, used is a polymer having a molecular weight and a molecular weight distribution well-controlled by a living radical polymerization of an unsaturated monomer.

Secondly, the polymer according to the present invention still has a living radical end group resulting from a living radical polymerization, i.e., a living radical end group that can generate stable free radicals which can be polymerized or reacted at any time under suitable reaction conditions.

Thirdly, used is a carbon nanotube obtained by being chemically bonded to the polymer having a living radical end group by a radical graft reaction as shown in FIG. 1.

In the present invention, the living radical polymerization of the unsaturated monomer may be performed by various methods. The methods may include an atom transfer radical polymerization, and a method using a tetramethyl piperidineoxyl (TEMPO), a stable free radical and its derivatives. However, the present invention is not limited to the living radical polymerization.

In the present invention, as a polymer reacted to a carbon nanotube by a grafting method, may be used any type of polymer having an affinity to a dispersion solution to be used. More concretely, when using a polar solvent such as water or alcohol as a dispersion solvent, an aqueous polymer is preferable. However, when using an organic solvent such as acetone, tetrahydrofurane, and dimethylformamide as a dispersion solvent, preferably applied is a polymer group that can be solved in the organic solvent or a polymer group having a high affinity to the organic solvent.

A molecular weight of the polymer is determined based on a dispersibility in a dispersion solvent of a polymer-grafted carbon nanotube (i.e., modified carbon nanotube), an electric conductivity and a catalytic reaction characteristic of a film composed of the modified carbon nanotube (i.e., carbon nanotube film), etc. When the polymer has a very high molecular weight, the modified carbon nanotube has enhanced dispersibility, a close adhesion strength between carbon nanotubes is enhanced, and an adhesion strength between a carbon nanotube and a substrate is enhanced. However, an electric conductivity of the carbon nanotube film is lowered, and an effective area of the carbon nanotube to a catalytic reaction is reduced, thereby lowering a catalytic reaction. Accordingly, used is a polymer synthesized to have a suitable molecular weight by a living radical polymerization according to a type of a selected polymer.

The polymer having a controlled molecular weight by a living radical polymerization still has a living radical functional group on its chain. As shown in FIG. 1, the living radical functional group generates polymer chains having free radicals under suitable reaction conditions. And, these radicals of the polymer chains are chemically bonded to carbon nanotubes, thereby preparing polymer-chain-grafted carbon nanotubes.

The polymer-chain-grafted carbon nanotubes prepared according to a first embodiment of the present invention form a very uniform dispersion liquid in water or a mixture solvent with water/ethyl alcohol. The conventional carbon nanotubes having undergone an acid or alkali process and an ultrasonic dispersion form a stable dispersion liquid, but are always observed to have been agglomerated onto a vessel wall. On the contrary, the modified carbon nanotubes according to the present invention form a very uniform dispersion solution with carbon nanotubes agglomerated to each other not being observed.

The dispersion solution that the modified carbon nanotube of the present invention is dispersed exhibits a very excellent dispersion characteristic without using the conventional organic binder such as carboxylmethylcellulose (CMC) or a dispersant such as triton X-100.

The nanotubes of the present invention may be at least one selected from single-walled carbon nanotubes (SWNT), double-wall carbon nanotube (DWNT), thin-wall carbon nanotube and multi-walled carbon nanotubes (MWNT).

Hereinafter, a carbon nanotube electrode and a preparation method thereof according to the present invention will be explained in more detail.

The carbon nanotube electrode according to the present invention comprises a substrate, and a carbon nanotube film formed on the substrate and including the aforementioned modified carbon nanotube.

The substrate, may be used as a transparent substrate on which a conductive electrode has been coated, a conductive substrate, or an insulating substrate. For instance, the substrate may be used as a transparent conductive substrate or a metallic substrate that fluorine-doped tin oxide (FTO) or indium-doped tin oxide (ITO) is coated on a glass substrate or a plastic substrate, or may be used as an insulating substrate such as a glass substrate having no conductivity, an alumina substrate, and a ceramic substrate.

The carbon nanotube film may be opaque or transparent. In the case of using a transparent substrate such as a glass substrate when the carbon nanotube film is transparent, a transparent nanotube electrode may be obtained. This transparent carbon nanotube electrode may replace the conventional expensive ITO or FTO substrate. Accordingly, the transparent carbon nanotube electrode of the present invention may be also used as a substrate of a semiconductor electrode, as well as a counter electrode of a dye-sensitized solar cell.

For the carbon nanotube electrode of the present invention, prepared is a dispersion solution that the modified carbon nanotube obtained in the above process is dispersed in a solvent. Then, a carbon nanotube film is formed on the substrate by using the dispersion solution. As the solvent, an organic solvent may be used, as well as a polar solvent such as water or a mixture solvent of water and ethyl alcohol.

A method for preparing a carbon nanotube film using a uniform dispersion solution that a modified carbon nanotube is dispersed may comprise a spraying or spinning method for spraying or spinning the dispersion solution on a substrate by using an electric field; and one method using the dispersion solution selected from a doctor blade method, a screen printing method, a spraying method, a spin coating method, a painting method and a dipping method. Here, the former spraying or spinning method using an electric field may be one of an electro-spraying method, an electro-blowning method and a flash spinning method, or a mixture therebetween.

In the present invention, particularly in consideration of a smoothness or uniformity of a coated carbon nanotube film, an adhesion strength between a carbon nanotube film and a substrate, a close adhesion strength between carbon nanotubes, the stability of the carbon nanotube film, and a catalytic characteristic and an electric conductivity of the carbon nanotube film, etc., the electro-spraying method may be very effectively used to prepare a carbon nanotube electrode having an excellent function. However, the present invention is not limited to the electro-spraying method, but various methods for spraying or spinning a solution by using an electric field may be used. For instance, may be used the conventional spraying methods such as an electro-blowning method for spraying a solution with air in an electro-spraying process and a method using an electric field in a flash spinning process using a solvent having a high volatility, or methods using a high voltage electric field together.

Hereinafter, will be explained one example of a method for forming a carbon nanotube electrode by coating a uniform dispersion solution of the modified carbon nanotube on a transparent conductive substrate by an electro-spraying method.

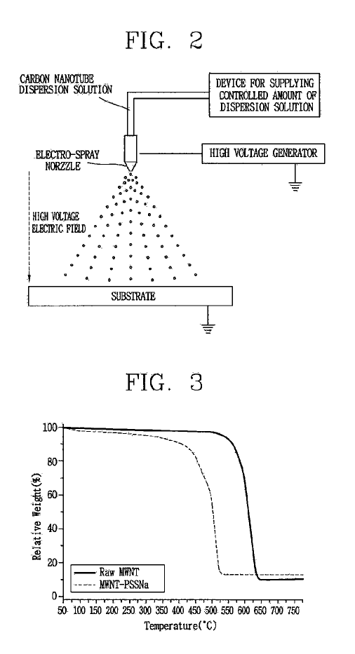

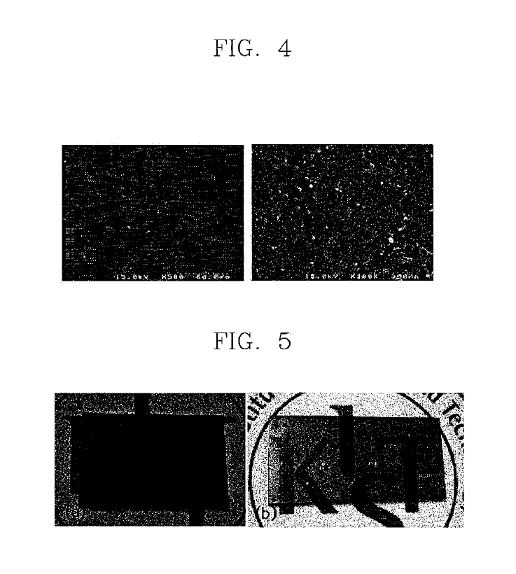

Referring to FIG. 2, an electro-spraying device comprises a spray nozzle connected to a quantitative pump for quantitatively injecting the carbon nanotube dispersion solution, a high voltage generator, a transparent conductive substrate on which sprayed carbon nanotubes are accumulated, etc. A high voltage more than 10 KV is applied between a grounded transparent conductive substrate (more concretely, a transparent conductive substrate having a conductivity of 5˜30Ω and on which ITO or FTO is coated) and a spray nozzle having a pump attached thereto, the pump configured to control a discharge amount per hour. At the same time, the uniform dispersion solution is discharged with a controlled speed of 1˜5000 μl/min, thereby preparing carbon nanotube films having various thicknesses.

More concretely, by using the electro-spray device of FIG. 2, a uniform dispersion solution that the modified carbon nanotube is dispersed in a suitable solvent without an additional organic binder is electro-sprayed on a transparent conductive substrate. In this process, the uniform dispersion solution is sprayed in the form of very minute drops. And, while being dispersed toward the substrate, the sprayed minute drops are adhered onto the substrate due to an adhesion strength between carbon nanotubes, as well as a rapid evaporation speed of the solvent. Accordingly, the modified carbon nanotube particles are attached onto the transparent conductive substrate with a high adhesion strength by a mechanism such as an electrostatic painting due to a high voltage electric field applied between the spray nozzle and the transparent conductive substrate. This allows a stable carbon nanotube film having a high smoothness, a high uniformity and a high density to be accumulated on the substrate.

If necessary, an electrode coated with the carbon nanotube film may be thermally compressed under suitable temperature and pressure conditions, thereby preparing a carbon nanotube electrode having a more dense structure.

In order to increase an electric conductivity of the carbon nanotube film, a highly uniform dispersion solution of nanocarbon black having a high conductivity may be electro-sprayed on the substrate together with the carbon nanotube dispersion solution by using an additional electro-spray nozzle. Accordingly, prepared is a carbon nanotube electrode that carbon nanotubes and nanocarbon black having a high conductivity are mixed to each other. In this case, preferably used is 0.1˜10% by weight of nanocarbon black based on 100% by weight of carbon nanotubes. And, more preferably used is 0.1˜5% by weight of nanocarbon black based on 100% by weight of carbon nanotubes. When the weight of the nanocarbon black exceeds 10% by weight, an electric conductivity of the carbon nanotube film is more increased, but an electrode stability is degraded due to a low adhesion strength between the carbon nanotube film and the substrate, and a low close adhesion strength between carbon nanotubes. The reason is because it is difficult to prepare a uniform dispersion solution of nanocarbon black having a high concentration. After the nanocarbon black is added to the carbon nanotube dispersion I solution, it is possible to spray or spin-coat the mixture.

In the present invention, the modified carbon nanotube inside the uniform dispersion solution preferably has a concentration of 10% by weight or less, and more preferably has a concentration of about 5% by weight. If the modified carbon nanotube has a high concentration, an electro-spray speed increases, and thus a carbon nanotube film having a predetermined thickness is accumulated on a substrate within a short time. However, since a close adhesion strength between carbon nanotube particles of the carbon nanotube film is lowered, an electric conductivity of the carbon nanotube film is lowered.

In the present invention, a potential difference of a high voltage applied between the spray nozzle and the substrate used for an electro-spray process is preferably 10 kV or more, and more preferably 15 kV or more. When the potential difference is high, a more stable carbon nanotube electrode can be obtained owing to a strong bonding force between carbon nanotube particles, and a high adhesion strength between the carbon nanotube film and the substrate.

The carbon nanotube electrode prepared by the above processes has an excellent adhesion strength between the carbon nanotube film and the substrate, and a close adhesion strength between carbon nanotube particles. Accordingly, the prepared carbon nanotube electrode has an excellent electric conductivity and catalytic characteristic even if its surface has been modified although a polymer is grafted.

Furthermore, the carbon nanotube electrode of the present invention has a low sheet resistance and an excellent electric conductivity, and forms a transparent electrode (refer to FIG. 5(b)). Accordingly, the carbon nanotube electrode itself may serve as a conductive substrate and a catalytic reaction occurs without using an expensive transparent conductive substrate such as ITO or FTO electrode. This may lower the price of a dye-sensitized solar cell when the carbon nanotube electrode of the present invention is used as a counter electrode and/or a transparent electrode for the dye-sensitized solar cell.

Also, the carbon nanotube electrode of the present invention has a film of a thickness much thinner than that of the conventional carbon nanotube electrode, thereby requiring a small amount of carbon nanotubes and thus being advantageous in the economic aspect. The carbon nanotube film of the present invention has a thickness of 0.05˜20 μm, preferably of 0.05˜10 μm, and more preferably of 0.05˜5 μm.

The carbon nanotube electrode prepared by the above processes may be used as a counter electrode for a dye-sensitized solar cell, which will be explained hereinafter.

The dye-sensitized solar cell of the present invention comprises a semiconductor electrode (anode), the carbon nanotube electrode (cathode), and an electrolyte filled between the two electrodes.

The semiconductor electrode is formed by coating a metal-oxide semiconductor film on a transparent conductive substrate, and by absorbing dye into a metal-oxide semiconductor that constitutes the metal-oxide semiconductor film. In the present invention, as the metal-oxide semiconductor, titanium oxide nanoparticles are used. However, the metal-oxide semiconductor of the present invention is not limited to the titanium oxide, but may include zinc oxide, tin oxide, niobium oxide, tungsten oxide, strontium oxide, zirconium oxide, or a mixture therebetween.

As a counter electrode of the semiconductor electrode, the aforementioned carbon nanotube electrode according to the present invention is used.

In order to assemble a counter electrode, a cathode with a semiconductor electrode, an anode, each conductive surface of the cathode and the anode is positioned toward inside. That is, the carbon nanotube film and the titanium oxide film are positioned to face each other. Here, a spacer having a thickness of about 20 μm and formed of a thermoplastic surlyn (made from Du Pont Corporation) is disposed between the cathode and the anode. Then, the two electrodes are attached to each other at a temperature of 120° C. Next, a liquid electrolyte or a polymer gel electrolyte is filled at a space between the two electrodes.

### Comparative Example 1

A Pt counter electrode for a dye-sensitized solar cell was prepared as follows.

Firstly, a solution that H₂PtCl₆ of a concentration of 0.5 mM was dissolved in isopropyl alcohol was drop-cast on a washed conductive FTO glass. Then, it was thermally treated at a temperature of 400° C. for 20 minutes, thereby preparing a Pt counter electrode. The Pt counter electrode was used to prepare a dye-sensitized solar cell, and features of the dye-sensitized solar cell were shown in Table 3.

### Comparative Example 2

A mixture composed of 40 g of distilled water, 0.8 g of multi-walled carbon nanotubes (MWNT of Table 1), 0.4 g of carboxyl methyl cellulose (CMC) serving as an organic binder, and 8×10⁻³ g of triton X-100 serving as a dispersant was grounded by a ball milling for 24 hours, thereby preparing paste. Then, the paste was coated on a conductive FTO glass substrate by using a doctor blade. Then, the coated paste was dried at a temperature of about 75° C. thus to prepare a carbon nanotube electrode having a thickness of about 20 μm. A sheet resistance of the prepared carbon nanotube electrode measured by a 4-point probe method was about 10.1 Ω/sq. The carbon nanotube electrode was used as a counter electrode for a dye-sensitized solar cell. Features of the dye-sensitized solar cell were shown in Table 3.

### Example 1

### 1-1 Synthesis of Polystyrenesulfonate Sodium Salt (PSSNa) Having a TEMPO End Group

40.0 g (194 mmol) of 4-styrenesulfonic acid sodium salt hydrate (SSNa) and 2.96 g (18.9 mmol) of TEMPO were dissolved in 200 mL of ethylene glycol. To the mixture solution, were slowly added a solution that 1.37 g (7.2 mmol) of Na₂S₂O₅ was dissolved in 15 mL of distilled water, and a solution that 2.59 g (9.6 mmol) of K₂S₂O₈ was dissolved in 45 mL of distilled water, at a temperature of 60° C. under a nitrogen atmosphere. Then, the resulting solution was stirred for one hour, thus to obtain PSSNa-TEMPO shown in FIG. 1. Next, a molecular weight of the PSSNa-TEMPO was measured by using water as an eluent and by using polystyrene having a standard molecular weight of polystyrene. As the result, obtained were a molecular weight (Mw) of 1020 and a molecular weight distribution (Mw/Mn) of 1.05.

### 1-2 (1) Synthesis of PSSNa-g-MWNT

20 mg of multi-walled carbon nanotubes (MWNT of Table 1) were added to 2 g of PSSNa-TEMPO synthesized in Example 1-1. Then, the mixture was stirred at a temperature of 120° C. for 24 hours. Next, PSSNa has been grafted to MWNT by a radical graft reaction, thereby synthesizing an MWNT-g-PSSNa. The synthesized MWNT-g-PSSNa was filtered, and then was re-dispersed to distilled water by using a ultra-sonicator. Then, the re-dispersed MWNT-g-PSSNa was filtered several times to be washed, and then was dried in a vacuum oven at a temperature of 80° C. for 12 hours. Elemental analysis results of the MWNT prior to the reaction and MWNT-g-PSSNa were shown in Table 1, and TGA analysis results thereof were shown in FIG. 3.

TABLE 1
Multi-walled carbon nanotubes(MWNT)

| | | |
|---|---|---|
| MWNT prior to | Average diameter | 9.5 nm |
| reaction | Average length | 1.5 μm |
| | Specific surface area | 250~300 m²/g |
| | Elementary Analysis(C:H:N) | 89.0:<0.3:<0.3 |
| Acid-treated MWNT | Elementary Analysis(C:H:N) | 83.23:0.25:0.33 |
| MWNT-g-PSSNa | Elementary Analysis(C:H:N:S) | |

2 g of MWNT prior to the reaction of Table 1 was added to 40 ml of nitric acid, and then was stirred at a room temperature for 24 hours thus to be filtered. Next, the filtered material was put into a solution of sulfuric acid and nitric acid (volume ratio of 3:1), and then was stirred at a room temperature for 48 hours to be filtered. Then, the resulting material was dried, thereby preparing MWNT treated with acid. The acid-treated MWNT has an acid-treated surface thus to have a functional group (—COOH) introduced thereto. Accordingly, the acid-treated MWNT has a more excellent disperse stability in water than MWNT having not undergone an acid-treatment.

0.5% by weight of the synthesized MWNT-g-PSSNa and 0.5% by weight of the acid-treated MWNT of the present invention were put into water, and then were dispersed for about 4 hours by using ultrasonic waves, respectively. Then, the resulting material underwent a centrifuging process for 3 hours by a centrifuge turning at 1000 rpm. Accordingly, whether the resulting material has been precipitated or not has been observed. Most of the MWNT was precipitated out of the acid-treated MWNT through centrifugation. On the contrary, the MWNT-g-PSSNa was not precipitated at all, but maintained a uniform dispersibility prior to the centrifugation.

### 1-3 (2) Synthesis of PSSNa-q-MWNT

The same method as the method in Example 1-2 was used, except that 20 mg of multi-walled carbon nanotubes (MWNT of Table 1) were added to 0.2 g of the PSSNa-TEMPO synthesized in Example 1-1

### Example 2

1.0% by weight of the MWNT-g-PSSNa synthesized in Example 1-2 was dispersed to a mixture solution between water and ethanol (1:1), respectively. Then, the MWNT-g-PSSNa dispersion solution was electro-sprayed on an FTO substrate by using the electro-spray device of FIG. 2, thereby forming carbon nanotube films having various thicknesses (Examples 2-1 to 2-7). And, a carbon nanotube film having a thickness of 1.65 μm was formed by using the MWNT-g-PSSNa synthesized in the Example 1-3 (Example 2-8). Here, a distance between the spray nozzle and the substrate was about 11 cm, and a voltage more than about 10 kV was applied to a space therebetween to prepare carbon nanotube electrodes. Some of the prepared carbon nanotube electrodes were thermally compressed with a pressure of 5.3 ton (5×5 cm) at a temperature of 150° C. for about 5 minutes. Then, each surface resistance of the prepared carbon nanotube electrodes was measured by a 4-point probe method, and the results were shown in the following Table 2.

As shown in FIG. 5, the carbon nanotube electrodes (Examples 2-1 to 2-7) prepared by using the MWNT-g-PSSNa prepared in Example 1-2 were opaque black. However, the carbon nanotube electrode (Examples 2-8) prepared by using the MWNT-g-PSSNa prepared in Example 1-3 were transparent. This means that the transparent carbon nanotube electrode of the present invention can replace ITO or FTO transparent electrode.

TABLE 2

| | Thickness of Carbon | |
|---|---|---|
| Samples | Nanotube Film (μm) | Sheet Resistance(Ω/sq) |
| Comparative | — | 8.39 |
| Example 1 | | |
| Comparative | 20.3 | 10.1 |
| Example 2 | | |
| Example 2-1 | 0.31 | 9.23 |
| Example 2-2 | 0.63 | 8.83 |
| Example 2-3 | 0.91 | 8.68 |
| Example 2-4 | 1.85 | 7.61 |
| Example 2-5 | 3.45 | 7.10 |
| Example 2-6 | 6.87 | 7.30 |
| Example 2-6* | 6.81 | 6.51 |
| Example 2-7 | 9.38 | 6.10 |
| Example 2-8 | 1.65 | 7.01 |
| Example 3 | 8.27 | 6.01 |
| Example 4 | 10.2 | 5.89 |

**Thermal Compression Sample

### Example 3

The same method as the method in Example 2 was used, except that an insulating glass substrate or a plastic film was used instead of a conductive FTO substrate when electro-spraying the MWNT-g-PSSNa dispersion solution. A surface resistance of the carbon nanotube electrode having a carbon nanotube film having a thickness of about 8.4 μm was measured by a 4-point probe method. And, the measured result was shown in Table 2.

### Example 4

To different electro-spray nozzles, respectively injected were a dispersion liquid obtained by dispersing 0.5% by weight of the MWNT-g-PSSNa synthesized in Example 1 to a mixture liquid of water and ethanol (1:1), and a dispersion solution obtained by dispersing 0.05% by weight of nanocarbon black to the mixture solution of water and ethanol (1:1). At the same time, the MWNT-g-PSSNa dispersion I solution and the nanocarbon black dispersion solution were electro-sprayed on an FTO substrate by using the electro-spray device of FIG. 2. Here, a spray amount of the nanocarbon black was controlled so that 5% by weight of the nanocarbon black based on the MWNT-g-PSSNa can be obtained, thereby forming a carbon nanotube film. A sheet resistance of a carbon nanotube to electrode having the prepared carbon nanotube film having a thickness of 10.2 μm was measured by a 4-point probe method. And, the result was shown in Table 2.

### Experimental Example

### 1. Preparation of Dye-Sensitized Solar Cell

To a Ti-Nanoxide D paste (Solarnonix) having a concentration of 11% formed in a mixture solvent of water/ethanol by using TiO₂ having a particle size of 13 nm and a specific surface area of 120 m²/g, 20% by weight of titanium tetraisopropoxide based on the weight of the TiO₂ was slowly added. Next, the paste was stirred for about 30 minutes, and then is deposited on a transparent conductive FTO glass substrate by a doctor blade method, thereby preparing a paste film. Then, the paste film was sintered at a temperature of 450° C. for about 30 minutes, thereby preparing a titanium oxide semiconductor electrode having a thickness of about 11 μm.

Then, dye was absorbed to the titanium oxide film formed on the transparent conductive FTO glass substrate. More concretely, a transparent conductive substrate on which a titanium oxide film is formed is impregnated, for at least 12 hours, into an ethanol solution in which ruthenium-based dye having a concentration of 3×10⁻⁴ M (N719) has been dissolved, thereby having the dye absorbed thereto. Then, the transparent conductive substrate was washed by ethyl alcohol and was dried, thereby preparing a semiconductor electrode having dye absorbed thereto.

Meanwhile, the electrodes prepared in Comparative Examples 1 and 2, and Example 2 were prepared as a counter electrode, respectively.

Next, a spacer with a thickness of about 20 μm was placed between the semiconductor electrode and the counter electrode. Then, the spacer was thermally compressed at a temperature of 120°, thereby attaching the two electrodes. Then, an iodine-based liquid electrolyte is filled in the space between the two electrodes and sealed, thereby preparing a dye-sensitized solar cell. Here, the iodine-based liquid electrolyte is composed of a solution that 0.6M of hexyldimethyl imidazolium iodine, 0.1M of guanidine thiocyanate, 0.03M of iodine, and 0.3M quaternary butylpyridine were dissolved in a mixture solution of acetonitrile/valeronitrile (volume ratio of 4:1).

### 2. Analysis of Photoelectric Characteristics of Dye-Sensitized Solar Cell

Photoelectric characteristics of a dye-sensitized solar cell were analyzed by using a Keithley 2400 source measure unit. As an optical source, Class A Solar Simulator Xe lamp (Yamashita Denso, 1000W) was used. A light intensity was controlled to AM-1.5 by using an Si reference solar cell mounted with a KG-5 filter (Fraunhoffer Institute, Germany). And, all samples were measured under a light intensity of 100 mW/cm² with AM1.5 Global.

### 3. Experimental Results

Characteristics of dye-sensitized solar cells using the electrodes prepared in Comparative Examples 1 and 2 and Example 2, as counter electrodes were shown in Table 3.

TABLE 3

| | | | | | Photoelectric |
|---|---|---|---|---|---|
| | Cell | | | Fill | Conversion |
| | Area | | | Factor | Efficiency |
| Samples | (cm²) | Voc(V) | Jsc(mA/cm²) | ff (%) | η(%) |
| Comparative | 0.281 | 0.699 | 14.63 | 0.64 | 6.52 |
| Example 1 | | | | | |
| Comparative | 0.261 | 0.724 | 14.05 | 0.62 | 6.32 |
| Example 2 | | | | | |
| Example 2-3 | 0.294 | 0.721 | 13.02 | 0.58 | 5.43 |
| Example 2-4 | 0.244 | 0.738 | 14.49 | 0.60 | 6.44 |
| Example 2-6 | 0.289 | 0.715 | 13.25 | 0.61 | 5.81 |
| Example 2-6* | 0.287 | 0.714 | 13.47 | 0.61 | 5.87 |
| Example 2-7 | 0.254 | 0.710 | 12.94 | 0.62 | 5.71 |

*Thermal Compression Sample

The foregoing embodiments and advantages are merely exemplary and are not to be construed as limiting the present disclosure. The present teachings can be readily applied to other types of apparatuses. This description is intended to be illustrative, and not to limit the scope of the claims. Many alternatives, modifications, and variations will be apparent to those skilled in the art. The features, structures, methods, and other characteristics of the exemplary embodiments described herein may be combined in various ways to obtain additional and/or alternative exemplary embodiments.

As the present features may be embodied in several forms without departing from the characteristics thereof, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. A modified carbon nanotube obtained by chemically bonding a polymer to a carbon nanotube by a radical graft reaction, the polymer synthesized by a living radical polymerization and having a living radical end group.

2. The modified carbon nanotube of claim 1, wherein the polymer is water-soluble or organic soluble.

3. The modified carbon nanotube of claim 1, wherein the carbon nanotube is a single-walled or a double-walled, or a thin-walled or a multi-walled carbon nanotube.

4. A method for preparing a modified carbon nanotube, comprising:
preparing a polymer synthesized by a living radical polymerization of an unsaturated monomer, and having a living radical end group; and
reacting the polymer with a carbon nanotube by a radical graft reaction, thereby chemically bonding the polymer to the carbon nanotube.

5. A carbon nanotube electrode, comprising:
a substrate; and
a carbon nanotube film formed on the substrate, and including the modified carbon nanotube according to claim 1.

6. The carbon nanotube electrode of claim 5, wherein the substrate is implemented as a transparent substrate on which a conductive electrode is coated, a conductive substrate, or an insulating substrate.

7. The carbon nanotube electrode of claim 5, wherein the carbon nanotube film further comprises nanocarbon black.

8. The carbon nanotube electrode of claim 5, wherein the substrate and the carbon nanotube film are transparent.

9. A method for preparing a carbon nanotube electrode, comprising:
preparing a dispersion liquid that the modified carbon nanotube prepared by the method according to claim 4 is dispersed in a solvent; and
forming a carbon nanotube film by depositing the dispersion solution on a substrate.

10. The method of claim 9, wherein the solvent is a polar solvent or an organic solvent.

11. The method of claim 9, wherein the carbon nanotube film is formed by using one of:
a spray or spinning method for spraying or spinning the dispersion solution on the substrate by using an electric field; and
a method using the dispersion solution selected from a doctor blade method, a screen printing method, a spray method, a spin coating method, a painting method and a dipping method.

12. The method of claim 11, wherein the spray or spinning method using an electric field is one of an electro-spray method, an electro-blown method and a flash spinning method, or a mixture therebetween.

13. The method of claim 9, wherein nanocarbon black is added to the dispersion solution thus to be sprayed or spin-coated, or an additional dispersion liquid containing nanocarbon black is sprayed or spin-coated.

14. The method of claim 9, further comprising thermally-compressing the carbon nanotube film.

15. A dye-sensitized solar cell, comprising:
a semiconductor electrode;
the carbon nanotube electrode according to claim 5; and
an electrolyte filled between the two electrodes.

16. The dye-sensitized solar cell of claim 15, wherein the carbon nanotube film of the carbon nanotube electrode has a thickness of 0.05˜20 μm.
